(19) United States
(12) Patent Application Publication
(10) Pub. No.: US 2008/0303379 A1
(43) Pub. Date: Dec. 11, 2008

(54) SURFACE ACOUSTIC WAVE DEVICE

(75) Inventors: Yasuharu NAKAI, Takatsuki-shi (JP); Kenji NISHIYAMA, Yasu-shi (JP); Takeshi NAKAO, Omihachiman-shi (JP); Masanori KATO, Kanazawa-shi (JP); Michio KADOTA, Kyoto-shi (JP)

Correspondence Address: MURATA MANUFACTURING COMPANY, LTD.;C/O KEATING & BENNETT, LLP, 1800 Alexander Bell Drive, SUITE 200, Reston, VA, 20191, US

(73) Assignee: MURATA MANUFACTURING CO., LTD., Nagaokakyo-shi (JP)

(21) Appl. No.: 12/190,618

(22) Filed: Aug. 13, 2008

Related U.S. Application Data
(63) Continuation of application No. PCT/JP2007/052017, filed on Feb. 6, 2007.

(30) Foreign Application Priority Data
Feb. 20, 2006 (JP) 2006-042822

(51) Int. Cl. H01L 41/107

(52) U.S. Cl. 310/313 R

(57) ABSTRACT

A surface acoustic wave device includes a LiNbO₃ substrate having Euler angles (0°±5°, θ, 0°±10°), electrodes that are disposed on the LiNbO₃ substrate, are primarily composed of Cu, and include an IDT electrode, a first silicon oxide film having substantially the same thickness as the electrodes and disposed in an area other than an area on which the electrodes including the IDT electrode are disposed, and a second silicon oxide film disposed on the electrodes and the first silicon oxide film, wherein the Euler angle θ and the normalized thickness H of the second silicon oxide film are selected to satisfy the formula 1 or 2:

−50×H^{2-3.5×}H+38.275≦{θ}≦10H+35 (wherein H<0.25) Formula 1

−50×H^{2-3.5}×H+38.275≦{θ}≦37.5 (wherein H>0.25) Formula 2.

### BACKGROUND OF THE INVENTION

1. Field of the Invention

The present invention relates to a surface acoustic wave device preferably for use, for example, as a resonator or a band-pass filter and, more particularly, to a surface acoustic wave device in which an IDT electrode and a silicon oxide film are provided on a LiNbO₃ substrate and which utilizes a Rayleigh wave.

2. Description of the Related Art

Band-pass filters used for an RF stage in mobile phones are required to operate for a wide frequency band over a wide range of temperatures. Thus, in existing surface acoustic wave devices, an IDT electrode is provided on a piezoelectric substrate of a rotated Y-cut X-propagating LiTaO₃ or LiNbO₃ substrate, and the IDT electrode is covered with a silicon oxide film. Because a piezoelectric substrate of this type has a negative temperature coefficient of frequency, an IDT electrode is covered with a silicon oxide film having a positive temperature coefficient of frequency to improve the temperature characteristics.

However, in such a structure, when the IDT electrode is made of widely-used Al or Al alloy, the IDT electrode cannot have a sufficient reflection coefficient. This often causes ripples in the resonance characteristics.

To solve such a problem, WO 2005-034347 discloses a surface acoustic wave device that includes a piezoelectric LiNbO₃ substrate having an electromechanical coupling coefficient K² of at least 0.025, an IDT electrode disposed on the piezoelectric substrate, the IDT electrode being made primarily of a metal having a density higher than that of Al, a first silicon oxide film disposed in an area other than an area where the IDT electrode is disposed, the first silicon oxide film having substantially the same thickness as the electrode, and a second silicon oxide film disposed on the electrode and the first silicon oxide film.

In the surface acoustic wave device disclosed in WO 2005-034347, the density of the IDT electrode is at least 1.5 times the density of the first silicon oxide film. WO 2005-034347, claimed that this high density results in a sufficient increase in the reflection coefficient of the IDT electrode and a reduction in the generation of ripples in the resonance characteristics.

However, in the surface acoustic wave device disclosed on WO 2005-034347, while the generation of ripples can be reduced in the vicinity of the resonance frequency, a relatively large spurious component was found at a frequency greater than the antiresonance frequency. More specifically, when the Rayleigh wave response is utilized, a large spurious component due to an SH wave response was produced in the vicinity of the antiresonance frequency at a frequency greater than the antiresonance frequency of the Rayleigh wave.

Furthermore, in the surface acoustic wave device disclosed in WO 2005-034347, when power is turned on, the resonance frequency and the antiresonance frequency sometimes shift greatly to higher frequencies. This abnormal frequency shift over the frequency shift due to heat generation occurs at turn-on. The resonance frequency returns to a designed resonance frequency after the electric power is turned off. However, there is a high demand for the prevention of this abnormal frequency shift at turn-on.

### SUMMARY OF THE INVENTION

To overcome the problems described above, preferred embodiments of the present invention provide a surface acoustic wave device that includes a silicon oxide film covering an IDT electrode to improve the temperature characteristics. In the surface acoustic wave device, not only the reflection coefficient of the IDT electrode is increased to reduce the generation of ripples in the resonance characteristics, but also the generation of a spurious component at a frequency greater than the antiresonance frequency of Rayleigh wave response is effectively reduced. Thus, the surface acoustic wave device according to preferred embodiments of the present invention has further improved frequency characteristics.

Preferred embodiments of the present invention also provide a surface acoustic wave device in which an abnormal resonance frequency shift at turn-on is reduced.

A preferred embodiment of the present invention provides a surface acoustic wave device utilizing a Rayleigh wave, including a LiNbO₃ substrate having Euler angles (0°±5°, θ, 0°±10°); electrodes that are disposed on the LiNbO₃ substrate, are primarily composed of Cu, and include at least one IDT electrode; a first silicon oxide film having substantially the same thickness as the electrodes and disposed in an area other than an area on which the electrodes are disposed; and a second silicon oxide film disposed on the electrodes and the first silicon oxide film, wherein the density of the electrodes is at least about 1.5 times the density of the first silicon oxide film, and the normalized thickness H of the second silicon oxide film and θ of the Euler angles (0°±5°, θ, 0°±10°) satisfy the formula (1) or (2).

−50×H²−3.5×H+38.275≦{θ}≦10H+35 (wherein H<0.25) Formula (1)

−50×H²−3.5×H+38.275≦{θ}≦37.5 (wherein H≧0.25) Formula (2)

According to a preferred embodiment of the present invention, the thickness of the second silicon oxide film preferably ranges from about 0.16λ to about 0.40λ, for example. In this case, the electromechanical coupling coefficient K_{SAW}² of a Rayleigh wave, which is a primary response to be utilized, is at least about 6%. Thus, the bandwidth of a surface acoustic wave device can be increased.

According to another preferred embodiment, the Euler angle θ of the LiNbO₃ substrate preferably ranges from about 34.5° to about 37.5°. In this case, the abnormal frequency shift at turn-on can be effectively reduced.

According to another preferred embodiment, the thickness of the second silicon oxide film disposed on the IDT electrode preferably ranges from about 0.16λ to about 0.30λ. In this case, the electromechanical coupling coefficient K_{SAW}² of a higher-mode Rayleigh wave is about 0.5% or less. Thus, the generation of a spurious component due to the higher-mode Rayleigh wave can be reduced.

According to another preferred embodiment, the duty ratio of the IDT electrode is preferably less than about 0.5. In this case, the abnormal frequency shift at turn-on can be more effectively reduced.

According to another preferred embodiment, the film thickness of the IDT electrode is preferably about 0.04λ or less. In this case, the abnormal frequency shift at turn-on can be reduced.

According to another preferred embodiment, the ratio of the cross width to the number of pairs of electrode fingers of the IDT electrode preferably ranges from about 0.075λ to about 0.25λ. In this case, the abnormal frequency shift at turn-on can be reduced effectively.

A surface acoustic wave device according to preferred embodiments of the present invention includes a LiNbO₃ substrate having Euler angles (0°±5°, θ, 0°±10°); electrodes and a first silicon oxide film each disposed on the LiNbO₃ substrate, the electrodes including at least one IDT electrode and having substantially the same thickness as the first silicon oxide film; and a second silicon oxide film disposed on the electrodes and the first silicon oxide film. As such, the first silicon oxide film and the second silicon oxide film improve the frequency-temperature characteristics.

In addition, the IDT electrode primarily composed of Cu has a density at least about 1.5 times that of the first silicon oxide film. Thus, as in the surface acoustic wave device described in WO 2005-034347, the generation of ripples in the resonance characteristics can be reduced.

Furthermore, the Euler angle θ and the normalized thickness H of the second silicon oxide film satisfy the formula (1) or (2). As is clear from the examples described below, this effectively reduces the generation of a spurious component due to an SH wave at a frequency greater than an antiresonance frequency of a fundamental Rayleigh wave response. This is because the electromechanical coupling coefficient K_{SAW}² of the SH wave is reduced to as low as about 0.1% or less.

Thus, preferred embodiments of the present invention provide a surface acoustic wave device that is rarely affected by a spurious component due to an SH wave and that has excellent resonance characteristics and filter characteristics.

Other features, elements, steps, characteristics and advantages of the present invention will become more apparent from the following detailed description of preferred embodiments of the present invention with reference to the attached drawings.

### BRIEF DESCRIPTION OF THE DRAWINGS

FIG. 1A is a schematic plan view of a surface acoustic wave device according to a first preferred embodiment of the present invention; FIG. 1B is a partially cutaway enlarged front cross-sectional view of a principal portion thereof.

FIG. 2 is a graph illustrating the electromechanical coupling coefficient K_{SAW}² of a Rayleigh wave as a function of θ of Euler angles (0°, θ, 0°) and the thickness of a second silicon oxide film in the first preferred embodiment of the present invention.

FIG. 3 is a graph illustrating the electromechanical coupling coefficient K_{SAW}² of a spurious component due to an SH wave as a function of θ of the Euler angles (0°, θ, 0°) and the thickness of the second silicon oxide film in the first preferred embodiment of the present invention.

FIG. 4 is a graph illustrating a region having an electromechanical coupling coefficient K_{SAW}² of the SH wave of about 0.1% or less as a function of the thickness of the second silicon oxide film and θ of the Euler angles (0°, θ, 0°).

FIG. 5A is a graph illustrating the electromechanical coupling coefficient K_{SAW}² as a function of the Euler angle θ of a LiNbO₃ substrate for various thicknesses of a Cu IDT electrode, in which the duty ratio of the IDT electrode is about 0.5 and the thickness of a second silicon oxide film is about 0.3λ; FIG. 5B is a graph illustrating the electromechanical coupling coefficient K_{SAW}² as a function of the Euler angle θ of a LiNbO₃ substrate for various thicknesses of a Cu IDT electrode, in which the duty ratio of the IDT electrode is about 0.5 and the thickness of a second silicon oxide film is about 0.4λ.

FIG. 6 is a graph illustrating the impedance and the phase as a function of frequency in a surface acoustic wave device according to a preferred embodiment of the present invention, when the thickness of a second silicon oxide film is about 0.24λ, about 0.29λ, or about 0.34λ.

FIG. 7 is a graph illustrating the attenuation as a function of frequency in a surface wave duplexer for use in PCS according to another preferred embodiment of the present invention and a comparative surface wave duplexer.

FIG. 8 is a graph illustrating the rate of divergence representing the frequency shift at turn-on as a function of θ of Euler angles (0°, θ, 0°).

FIG. 9 is a graph illustrating the rate of divergence representing the abnormal frequency shift at turn-on as a function of the duty ratio of an IDT electrode.

FIG. 10 is a graph illustrating the rate of divergence as a function of the thickness of a Cu IDT electrode.

FIG. 11 is a graph illustrating the rate of divergence as a function of the thickness of a SiN film, which functions as a frequency adjustment film.

FIG. 12 is a graph illustrating the rate of divergence as a function of the ratio of the cross width to the number of pairs of electrode fingers of an IDT electrode.

FIG. 13 is a graph illustrating the attenuation as a function of frequency in a high-frequency region in a surface wave duplexer for use in PCS.

FIG. 14 is a graph illustrating the electromechanical coupling coefficient K_{SAW}² of a higher-mode Rayleigh wave as a function of the thickness of a second silicon oxide film in the surface wave duplexer described in FIG. 13.

### DETAILED DESCRIPTION OF PREFERRED EMBODIMENTS

The present invention will be further described below with specific preferred embodiments of the present invention with reference to the attached drawings.

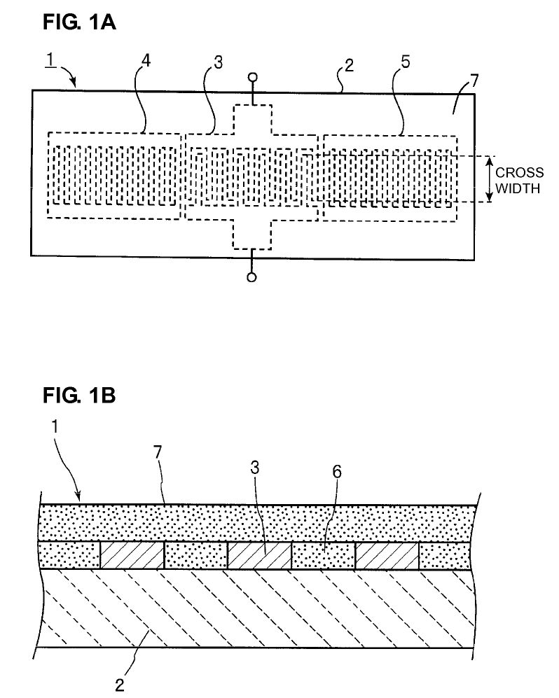

FIG. 1A is a schematic plan view of a surface acoustic wave device according to a preferred embodiment of the present invention; FIG. 1B is a partially cutaway enlarged front cross-sectional view of a principal portion thereof.

A surface acoustic wave device 1 includes a rotated Y-cut X-propagating LiNbO₃ substrate 2. The LiNbO₃ substrate 2 has the crystal orientation of Euler angles (0°, θ, 0°).

As illustrated in FIG. 1B, an IDT electrode 3 is disposed on the LiNbO₃ substrate 2. As illustrated in FIG. 1A, reflectors 4 and 5 are disposed on both sides of the IDT electrode 3 in the propagation direction of a surface wave.

These electrodes are surrounded by a first silicon oxide film 6. The first silicon oxide film 6 preferably has substantially the same thickness as the IDT electrode 3 and the reflectors 4 and 5. These electrodes and the first silicon oxide film 6 are covered with a second silicon oxide film 7.

In the surface acoustic wave device 1, the LiNbO₃ substrate has a negative temperature coefficient of frequency. On the other hand, the first silicon oxide film 6 and the second silicon oxide film 7 have a positive temperature coefficient of frequency. This combination improves the frequency characteristics.

Furthermore, the density of the electrodes including the IDT electrode 3 is at least about 1.5 times the density of the first silicon oxide film 6. In the present preferred embodiment, the IDT electrode 3 is composed of Cu. The density of the IDT electrode 3 is about 8.93 g/cm³, and the density of the first silicon oxide film is about 2.21 g/cm³.

Thus, as described in WO 2005-034347, the IDT electrode 3 has an increased reflection coefficient. This is believed to reduce the generation of ripples in the resonance characteristics.

In the surface acoustic wave device 1 according to the present preferred embodiment, the Euler angle θ of the LiNbO₃ substrate 2 and the normalized thickness H of the second silicon oxide film 7 satisfy the formula (1) or (2) described below. This results in an effective reduction in the generation of a spurious component at a frequency greater than the antiresonance frequency of Rayleigh wave response. The present invention will be further described in the following examples of preferred embodiments thereof.

−50×H²−3.5×H+38.275≦{θ}≦10H+35 (wherein H<0.25) Formula (1)

−50×H²−3.5×H+38.275≦{θ}≦37.5 (wherein H≧0.25) Formula (2)

### EXAMPLE 1

A plurality of LiNbO₃ substrates having different Os of Euler angles (0°, θ, 0°) was prepared. A Cu IDT electrode 3 having a thickness of about 0.04λ and a duty ratio of about 0.50 was provided on the LiNbO₃ substrate 2. The number of electrode finger pairs of the IDT electrode 3 was 120. The cross width of the electrode finger pairs was about 32.3 μm. Furthermore, reflectors 4 and 5 made of the same material as the IDT electrode 3 and having the same thickness as the IDT electrode 3 were provided on both sides of the IDT electrode 3 in the propagation direction of a surface wave. Each of the reflectors 4 and 5 has 20 electrode fingers.

The surface acoustic wave device 1 was produced as follows. The first silicon oxide film was formed on the LiNbO₃ substrate by sputtering. After a resist pattern was formed on the first silicon oxide film, the first silicon oxide film was etched by reactive ion etching to form grooves for electrodes on the LiNbO₃ substrate. The grooves were filled with Cu to define the IDT electrode 3 and reflectors 4 and 5.

The second silicon oxide film was then formed by sputtering. The surface acoustic wave device 1 was thus produced the second silicon oxide film having a thickness of about 0.15λ, about 0.20λ, about 0.25λ, about 0.30λ, about 0.35λ, or about 0.40λ.

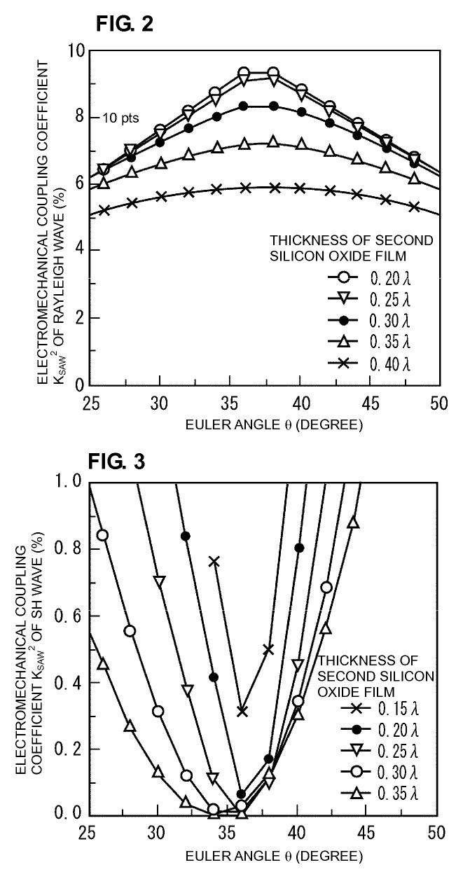

FIG. 2 shows the electromechanical coupling coefficient K_{SAW}² of a Rayleigh wave as a function of Euler angle θ and the thickness of the second silicon oxide film in the surface acoustic wave device 1.

FIG. 2 shows that the electromechanical coupling coefficient K_{SAW}² increases with decreasing thickness of the second silicon oxide film. FIG. 2 also shows that the electromechanical coupling coefficient K_{SAW}² is large at an Euler angle θ in the range of about 30° to about 45°, particularly in the range of about 35° to about 40°.

Thus, the electromechanical coupling coefficient K_{SAW}² of a Rayleigh wave varies with the Euler angle θ and the thickness of the second silicon oxide film.

FIG. 3 shows the electromechanical coupling coefficient K_{SAW}² of a spurious component due to an SH wave as a function the Euler angle θ and the thickness of the second silicon oxide film 7 in the surface acoustic wave device 1.

FIG. 3 shows that the electromechanical coupling coefficient K_{SAW}² of an SH wave increases with decreasing thickness of the second silicon oxide film 7. FIG. 3 also shows that the electromechanical coupling coefficient K_{SAW}² of an SH wave is small at an Euler angle θ in the range of about 30° to about 40° and smallest at about 35°.

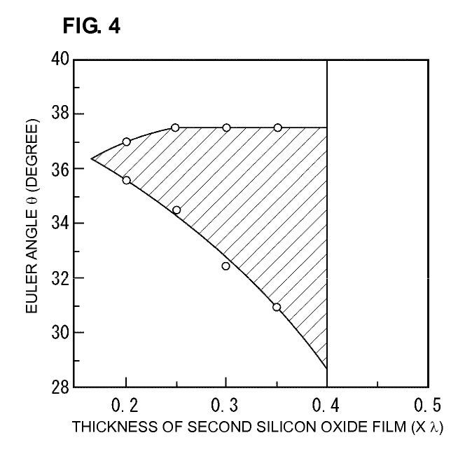

On the basis of the results shown in FIGS. 2 and 3, FIG. 4 shows a region in which the Euler angle θ and the normalized thickness H of the second silicon oxide film provide the electromechanical coupling coefficient K_{SAW}² of a spurious component due to an SH wave of about 0.1% or less (hatched region). In the hatched region in FIG. 4 where the electromechanical coupling coefficient K_{SAW}² of an SH wave is about 0.1% or less, the spurious component due to the SH wave is substantially negligible when the surface acoustic wave device 1 is used.

The hatched region in FIG. 4 satisfies the formula (1) or (2).

Thus, when the Euler angle θ of the LiNbO₃ substrate 2 and the thickness of the second silicon oxide film 7 are selected to satisfy the formula (1) or (2), the electromechanical coupling coefficient K_{SAW}² of a spurious component due to an SH wave is about 0.1% or less.

### EXAMPLE 2

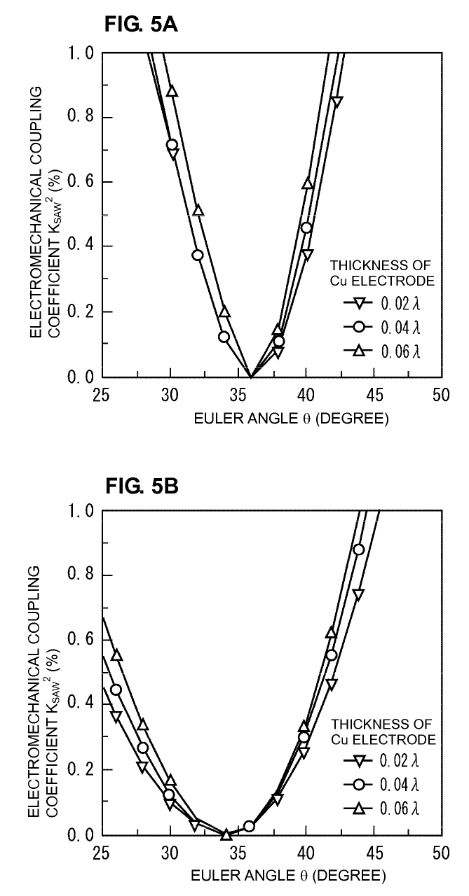

Another surface acoustic wave device that includes a second silicon oxide film having a thickness of about 0.3λ or about 0.4λ and an IDT electrode having a thickness of about 0.02λ, about 0.04λ, or about 0.06λ was produced in the same manner as the surface acoustic wave device 1 according to Example 1. FIGS. 5A and 5B show the electromechanical coupling coefficient of an SH wave as a function of Euler angle θ and the thickness of the IDT electrode in the surface acoustic wave device 1 according to Example 2. FIGS. 5A and 5B show the results for the thickness of the second silicon oxide film 7 of about 0.3λ and about 0.4λ, respectively.

FIGS. 5A and 5B show that, in both cases, the relationship between the Euler angle θ and the thickness H of the second silicon oxide film 7 that provides the electromechanical coupling coefficient K_{SAW}² of about 0.1% or less does not change significantly, even when the thickness of the IDT electrode 3 varies within the range of about 0.02λ to about 0.06λ.

In the practical use of the surface acoustic wave device 1, the electromechanical coupling coefficient K_{SAW}² of a Rayleigh wave should be at least about 5%. Accordingly, as shown in FIG. 2, the thickness of the second silicon oxide film is preferably about 0.4λ or less. Furthermore, as shown in FIG. 4, the thickness of the second silicon oxide film is preferably at least about 0.16λ.

### EXAMPLE 3

To verify the results shown in FIG. 4, the frequency characteristics of a surface acoustic wave device were examined. A single-port surface acoustic wave resonator having a resonance frequency of about 1.9 GHz was produced using a LiNbO₃ substrate having Euler angles (0°, 34°, 0°). The λ was about 2.07 μm.

More specifically, a first silicon oxide film having a thickness of about 0.039λ was provided on the LiNbO₃ substrate 2. After a resist pattern was formed on the first silicon oxide film, the first silicon oxide film was selectively etched by reactive ion etching to form grooves for electrodes. The grooves were filled with Cu to form an IDT electrode 3 and reflectors 4 and 5. These electrodes had a thickness of about 0.039λ, which is about 80 nm. A second silicon oxide film 7 was then formed on the IDT electrode to produce a surface acoustic wave device. The thickness of the second silicon oxide film 7 was about 500 nm (about 0.24λ), about 600 nm (about 0.29λ), or about 700 nm (about 0.34λ).

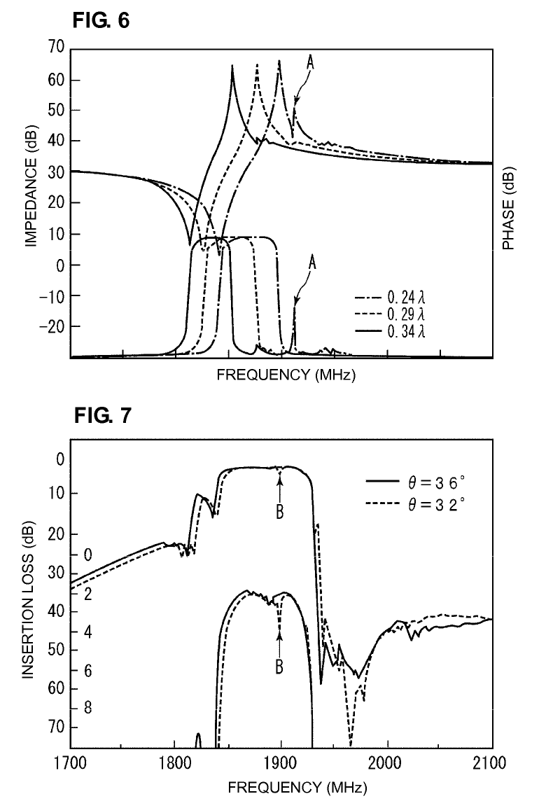

FIG. 6 shows the impedance and the phase as a function of frequency in the surface acoustic wave device 1 thus produced.

FIG. 6 shows the presence of a very large spurious component, as indicated by an arrow A, probably due to an SH wave at a frequency greater than the antiresonance frequency when the thickness of the second silicon oxide film 7 was about 500 nm or about 0.24λ. By contrast, such a large spurious component did not occur at a frequency greater than the antiresonance frequency when the thickness of the second silicon oxide film was about 600 nm (about 0.29λ) or about 700 nm (about 0.34λ).

At θ equal to about 34°, the thickness of the second silicon oxide film of about 0.29λ or about 0.34λ satisfies the formula (2). Thus, the spurious component due to an SH wave is reduced. By contrast, the thickness of the second silicon oxide film of about 500 nm or about 0.24λ satisfies neither formula (1) nor formula (2), thus resulting in the generation of the large spurious component due to an SH wave.

### EXAMPLE 4

A duplexer for use in PCS was produced in the same manner as the single-port surface acoustic wave resonator described above. The waveform of a band-pass filter in the duplexer was measured. The electrode material was composed of Cu. The thickness of an electrode and a first silicon oxide film 6 was about 0.05λ (about 98 nm). The thickness of the second silicon oxide film 7 was about 0.27λ (about 531 nm). A SiN frequency adjustment film was formed on the second silicon oxide film 7 to adjust the frequency. More specifically, the thickness of the SiN film was adjusted while the SiN film was formed. Alternatively, after the SiN film was formed, the SiN film was etched by reactive ion etching or ion milling to reduce the thickness, thus achieving a desired frequency. The frequency adjustment film may be made of another material, such as SiC or Si, for example.

FIG. 7 shows the attenuation as a function of frequency in a band-pass filter of the surface wave duplexer for use in PCS thus produced. FIG. 7 shows two examples. In one example (broken line), the Euler angle θ was about 32°, and neither the formula (1) nor the formula (2) were satisfied. In the other example (solid line), the Euler angle θ was about 36°, and the formula (1) was satisfied. Two curves shown in a lower portion of FIG. 7 are the attenuations expressed with an enlarged scale shown on the right side of the vertical axis.

FIG. 7 shows that a large spurious component due to an SH wave occurs in the passband at an Euler angle θ of about 32°, as indicated by an arrow B. By contrast, no spurious component occurs when the formula (1) is satisfied at an Euler angle θ of about 36°.

### EXAMPLE 5

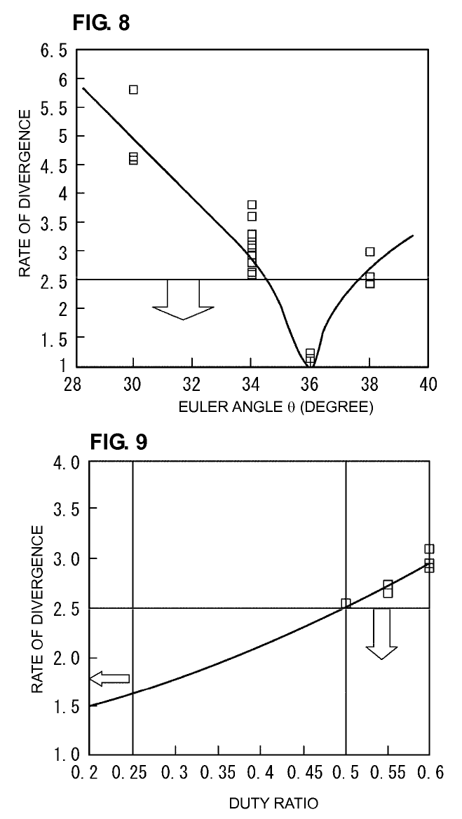

The same surface acoustic wave device 1 as described above was produced, and the frequency variation at turn-on was measured. More specifically, a surface acoustic wave device 1 was produced as in Example 1, except that the thickness of the Cu IDT electrode and the first silicon oxide film was about 0.05λ, the thickness of the second silicon oxide film 7 was about 0.30λ, and a SiN film having a thickness of about 15 nm was provided as a frequency adjustment film on the second silicon oxide film. The duty ratio of the IDT electrode 3 was about 0.55. The LiNbO₃ substrate 2 had an Euler angle θ of about 30°, about 34°, about 36°, or about 38°. FIG. 8 shows the rate of divergence representing the frequency shift at turn-on as a function of Euler angle θ in the surface acoustic wave device 1. The rate of divergence was calculated by the following equation.

Rate of divergence=(frequency variation when an electric power of about 0.9 W is applied)/(frequency variation based on TCF when the temperature increases to about 60° C.)

Thus, in the surface acoustic wave device, when power is turned on, the temperature increases from room temperature to about 60° C. An increase in temperature at turn-on somewhat varies the frequency. The rate of divergence was defined by the ratio of a frequency variation at the application of an electric power of about 0.9 W to a frequency variation due to an increase in temperature. Thus, at a rate of divergence of about 1, the frequency variation is caused only by an increase in temperature. An increase in rate of divergence indicates the presence of abnormal frequency shift, in addition to the frequency variation due to an increase in temperature.

For example, in a surface acoustic wave device having a TCF of about −5 ppm/° C., the frequency variation caused by a temperature increase to about 60° C. is estimated to be about −300 ppm. When the frequency variation due to the application of an electric power of about 0.9 W is about −900 ppm, the rate of divergence is (−900)/(−300)=3.

FIG. 8 shows that the rate of divergence is almost one at an Euler angle θ of about 36°, indicating the substantial absence of abnormal frequency shift. The rate of divergence increases as the Euler angle θ departs from about 36°.

While the rate of divergence is ideally one, a rate of divergence of about 2.5 or less can be achieved at an Euler angle θ in the range of about 34.5° to about 37.5°, as shown in FIG. 8.

Thus, in the present invention, the Euler angle θ preferably ranges from about 34.5° to about 37.5°.

At a rate of divergence of more than about 2.5, the frequency variation is too large to stabilize the characteristics at turn-on.

### EXAMPLE 6

A surface acoustic wave device 1 was produced as in Example 5, except that the LiNbO₃ substrate had the Euler angle θ of about 34°, the thickness of the second silicon oxide film 7 was about 0.30λ, and the duty ratio of the IDT electrode 3 ranged from about 0.2 to about 0.65. FIG. 9 shows the rate of divergence in the surface acoustic wave device 1.

FIG. 9 shows that the rate of divergence advantageously decreases with decreasing duty ratio of the IDT electrode. A rate of divergence of about 2.5 or less can be achieved at a duty ratio of the IDT electrode of about 0.5 or less.

However, an excessively low duty ratio of the IDT electrode results in an excessively high electrode resistance, thus making the use of the surface acoustic wave device difficult. The duty ratio of the IDT electrode is therefore preferably at least about 0.25. Thus, the duty ratio of the IDT electrode preferably ranges from about 0.25 to about 0.5.

### EXAMPLE 7

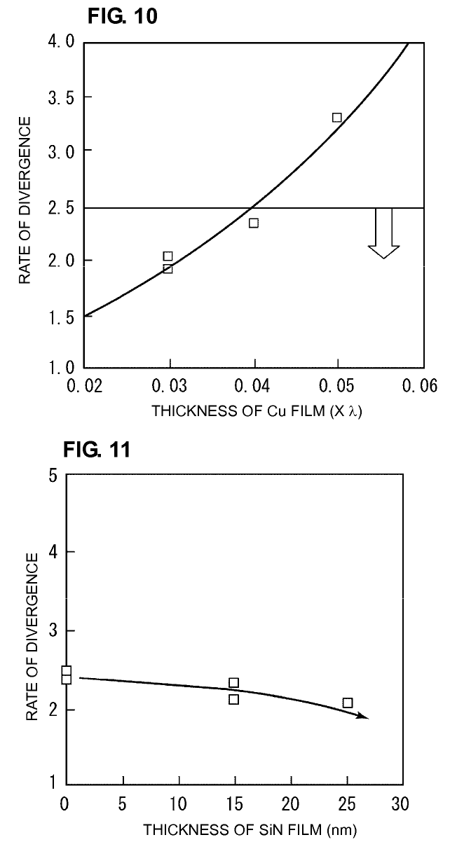

A surface acoustic wave device 1 was produced as in Examples 5 and 6, except that the LiNbO₃ substrate 2 had an Euler angle θ of about 34°, the duty ratio of the Cu IDT electrode 3 was about 0.55, the thickness of the second silicon oxide film 7 was about 0.30λ, an SiN frequency adjustment film having a thickness of about 15 nm was formed at the top, and the thickness of the Cu IDT electrode 3 ranged from about 0.03λ to about 0.05λ. FIG. 10 shows the rate of divergence as a function of the thickness of the Cu IDT electrode 3 in the surface acoustic wave device 1.

FIG. 10 shows that the rate of divergence decreases with decreasing thickness of the IDT electrode 3. A rate of divergence of about 2.5 or less can be achieved at a thickness of the IDT electrode 3 of about 0.04λ or less. The thickness of the IDT electrode 3 is therefore preferably about 0.04λ or less.

### EXAMPLE 8

A surface acoustic wave device 1 was produced as in Example 7, except that the SiN frequency adjustment film had a thickness of about 15 or about 25 nm. For purposes of comparison, a surface acoustic wave device without a SiN film was also produced. Other parameters were the same as in Example 7; that is, the Euler angle θ was about 34°, the IDT electrode was composed of Cu and had a thickness of about 0.05λ, and the second silicon oxide film had a thickness of about 0.30λ. FIG. 11 shows the results. FIG. 11 shows that the rate of divergence decreases with increasing the thickness of the SiN film thickness. Thus, the SiN film preferably has a large thickness.

### EXAMPLE 9

Surface acoustic wave devices having different ratio of the cross width to the number of pairs of electrode fingers of the IDT electrode 3 were produced to investigate the relationship between the cross width and the number of pairs of electrode fingers. The LiNbO₃ substrate 2 had an Euler angle θ of about 34°, the thickness of the Cu IDT electrode 3 was about 0.05λ, the thickness of the second silicon oxide film 7 was about 0.30λ, the thickness of the SiN frequency adjustment film was about 15 nm, and the duty ratio of the IDT electrode 3 was about 0.55. The ratio of the cross width to the number of pairs of electrode fingers was about 0.058λ, about 0.077λ, about 0.11λ, or about 0.23λ.

The cross width refers to the length of crossing portions, in the propagation direction of a surface wave, of adjacent electrode fingers having different electric potentials in the IDT electrode 3.

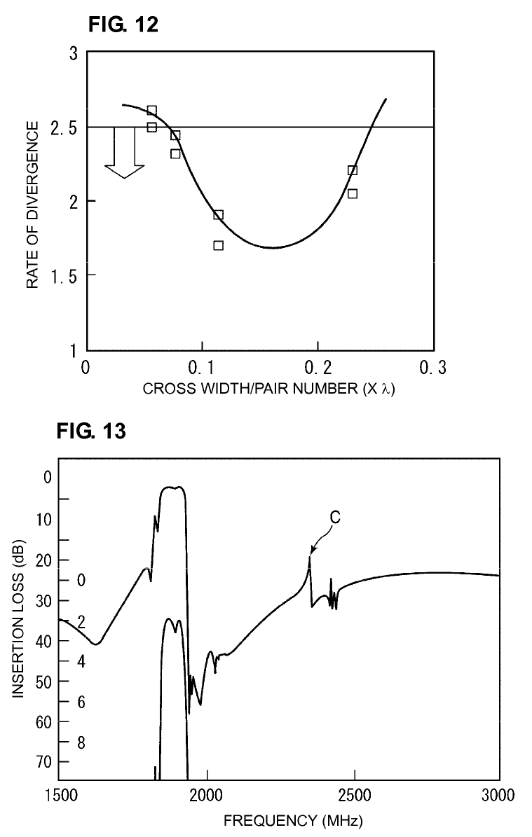

FIG. 12 shows that the rate of divergence is four or less at a ratio of the cross width to the number of pairs of electrode fingers in the range of about 0.075λ to about 0.25λ. Thus, this range is preferred. The rate of divergence is about 2.5 or less at a ratio of the cross width to the number of pairs of electrode fingers in the range of about 0.12λ to about 0.2λ. Thus, this range is more preferred.

### EXAMPLE 10

FIG. 13 shows the frequency characteristics of the surface wave duplexer for use in PCS described above in a high-frequency region of at least about 1500 MHz. The frequency characteristics show in FIG. 13 corresponds to those in a high-frequency region of the frequency characteristics shown in FIG. 7.

FIG. 13 shows the presence of a spurious component, as indicated by an arrow C, at about 2300 MHz, which is higher than the frequency of Rayleigh wave response of interest. This spurious component is caused by a higher-mode Rayleigh wave. While the spurious component is apart from a fundamental Rayleigh wave response to some extent, the spurious component is desirably small. The present inventors found that the spurious component due to the higher-mode Rayleigh wave can be reduced by altering the thickness of the second silicon oxide film 7.

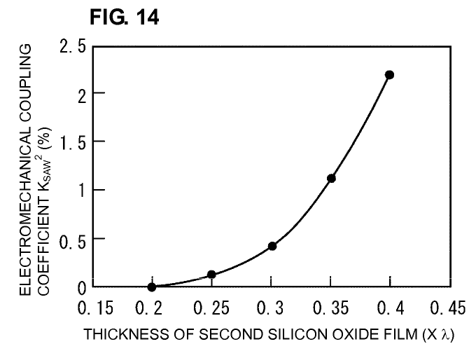

FIG. 14 is a graph illustrating the electromechanical coupling coefficient K_{SAW}² of the higher-mode Rayleigh wave as a function of the thickness of the second silicon oxide film 7 in the surface wave duplexer described above. The LiNbO₃ substrate 2 had an Euler angle θ of about 36°, the IDT electrode 3 was composed of Cu and had a thickness of about 0.05λ, and the duty ratio was about 0.50.

FIG. 14 shows that the spurious component due to a higher-mode Rayleigh wave was reduced with decreasing thickness of the second silicon oxide film 7. In particular, the electromechanical coupling coefficient of a higher-mode Rayleigh wave is preferably about 0.5% or less to achieve characteristically required attenuation. Accordingly, the thickness of the second silicon oxide film 7 is preferably about 0.3λ or less.

While the electrodes, including the IDT electrode 3, were composed of Cu in the preferred embodiments and the examples described above, the electrodes in the present invention may be made of any material based on Cu. For example, the electrodes may be a film made of Cu, or may be a laminate film of a Cu film and a film made of a metal other than Cu or an alloy film. The electrodes made of a laminate film are primarily composed of a Cu film. The IDT electrode may be formed of an alloy primarily composed of Cu. The electrodes may be made of a laminate primarily composed of an alloy film mainly composed of Cu.

The present invention can be applied to various resonators and surface wave filters of various circuitry, as well as the single-port surface acoustic wave resonator and the band-pass filter of the duplexer described above.

While preferred embodiments of the present invention have been described above, it is to be understood that variations and modifications will be apparent to those skilled in the art without departing the scope and spirit of the present invention. The scope of the present invention, therefore, is to be determined solely by the following claims.

What is claimed is:

1. A surface acoustic wave device utilizing a Rayleigh wave, comprising:
a LiNbO₃ substrate having Euler angles (0°±5°, θ, 0°±10°);
electrodes disposed on the LiNbO₃ substrate, primarily composed of Cu, and including at least one IDT electrode;
a first silicon oxide film having substantially the same thickness as that of the electrodes and disposed in an area other than an area in which the electrodes are disposed; and
a second silicon oxide film disposed on the electrodes and the first silicon oxide film; wherein
a density of the electrodes is at least about 1.5 times a density of the first silicon oxide film; and
a normalized thickness H of the second silicon oxide film and θ of the Euler angles (0°±5°, θ, 0°±10°) satisfy the Formula 1 or 2:
−50×H²−3.5×H+38.275≦{θ}≦10H±35 (wherein H<0.25) Formula 1
−50×H²−3.5×H+38.275≦{θ}≦37.5 (wherein H≧0.25) Formula 2.

2. The surface acoustic wave device according to claim 1, wherein the thickness of the second silicon oxide film ranges from about 0.16λ to about 0.40λ.

3. The surface acoustic wave device according to claim 1, wherein the Euler angle θ ranges from about 34.5° to about 37.5°.

4. The surface acoustic wave device according to claim 1, wherein the thickness of the second silicon oxide film ranges from about 0.16λ to about 0.30λ.

5. The surface acoustic wave device according to claim 1, wherein a duty ratio of the IDT electrode is less than about 0.5.

6. The surface acoustic wave device according to claim 1, wherein the thickness of the electrodes is about 0.04λ or less.

7. The surface acoustic wave device according to claim 1, wherein a ratio of the cross width to the number of pairs of electrode fingers of the IDT electrode ranges from about 0.075λ to about 0.25λ.
